(19) United States
(12) Patent Application Publication
(10) Pub. No.: US 2013/0328068 A1
(43) Pub. Date: Dec. 12, 2013

(54) DEVICES, SYSTEMS, AND METHODS RELATED TO DISTRIBUTED RADIATION TRANSDUCERS

(71) Applicant: Martin F. Schubert, Boise, ID (US)

(72) Inventor: Martin F. Schubert, Boise, ID (US)

(73) Assignee: MICRON TECHNOLOGY, INC., Boise, ID (US)

(21) Appl. No.: 13/490,328

(22) Filed: Jun. 6, 2012

(51) Int. Cl. H01L 25/075; H01L 21/782

(52) U.S. Cl. 257/88; 438/28; 257/E25.02; 257/E21.598

(57) ABSTRACT

Radiation-transducer devices, e.g., lighting-emitting devices, including radiation transducers, e.g., light-emitting diodes, and associated devices, systems, and methods are disclosed herein. A radiation-transducer device configured in accordance with a particular embodiment includes a base structure including a first lead, a cap structure including a second lead, and a plurality of radiation transducers irregularly distributed between the base structure and the cap structure. The radiation transducers are non-uniformly oriented relative to the first and second leads and the device is configured to intermittently power the radiation transducers using an alternating current. A method for manufacturing radiation-transducer devices in accordance with a particular embodiment includes distributing a plurality of radiation transducers onto a base structure or a cap structure without individually handling the radiation transducers. The radiation transducers are introduced via a mixture including the radiation transducers and a non-solid carrier medium.

### TECHNICAL FIELD

The present technology is related to radiation-transducer devices, e.g., lighting-emitting devices including light-emitting diodes. In particular, some embodiments of the present technology are related to incorporating distributed light-emitting diodes into lighting-emitting devices to enhance the uniformity of light output over relatively large areas.

### BACKGROUND

Solid-state radiation transducers (SSRTs), e.g., light-emitting diodes (LEDs), organic light-emitting diodes, and polymer light-emitting diodes, are used in numerous modern devices for backlighting, general illumination, and other purposes. SSRTs typically include p-n junctions and can have a variety of configurations differing, for example, with respect to the positions of electrical contacts of the p-sides and the n-sides of the p-n junctions. For example, FIG. 1 illustrates a conventional LED 100 having a lateral configuration of electrical contacts. The LED 100 includes a growth substrate 102 under a junction structure 104 having an active region 106 between an n-type material 108 and a p-type material 110. The LED 100 further includes a first contact 112 electrically coupled to the p-type material 110 and a second contact 114 electrically coupled to the n-type material 108. As shown in FIG. 1, the first and second contacts 112, 114 are laterally offset from each other on the same side of the LED 100. As another example, FIG. 2 illustrates a conventional LED 200 having a vertical configuration of electrical contacts. The LED 200 includes a carrier substrate 202 and a junction structure 204 having an active region 206 positioned between an n-type material 208 and a p-type material 210. Manufacturing the LED 200 can include forming the n-type material 208, the active region 206, and the p-type material 210 sequentially on a growth substrate (not shown) similar to the growth substrate 102 shown in FIG. 1. A first contact 212 can then be formed on the p-type material 210, and the carrier substrate 202 can be attached to the first contact 212. The growth substrate can then be removed and a second contact 214 formed, e.g., in a pattern, on the n-type material 208. The LED 200 can then be inverted to produce the orientation shown in FIG. 2. As shown in FIG. 2, the first and second contacts 212, 214 are superimposed with each other on opposite sides of the LED 200.

In most cases, LED light output is relatively intense. For example, the radiant fluxes per unit area of gallium nitride white LEDs are often on the order of thousands of lumens per square centimeter. This can be disadvantageous when distributing light over a wide area is desirable, e.g., in many display, backlighting, and architectural lighting applications. To increase the distribution of light output, some conventional light-emitting devices include multiple, spaced-apart LEDs. In these devices, both the power of the individual LEDs and the quantity of LEDs affect the total light output. Light output from a single LED typically is directly proportional to the size of the LED, e.g. the size of an active region of the LED. The same light output, therefore, can be achieved using a smaller number of larger LEDs or a larger number of smaller LEDs. The cost associated with individually packaging LEDs and incorporating the packaged LEDs into light-emitting devices is often similar for LEDs of different sizes. As a result, in most cases, using a smaller number of larger LEDs reduces manufacturing costs relative to using a larger number of smaller LEDs. There is an incentive, therefore, to use relatively large LEDs in light-emitting devices including multiple LEDs.

When relatively large LEDs are spaced apart and simultaneously illuminated, the resulting light output can appear uneven. Since light diffuses and becomes more uniform at greater distances from a source, uneven light output typically is most problematic in applications involving relatively short-range illumination. Even in applications involving relatively long-range illumination, uneven light output from a light-emitting device can be undesirable. For example, in some architectural lighting applications, visible bright spots associated with individual LEDs can be aesthetically unappealing. To enhance the uniformity of light output, light-emitting devices including multiple LEDs often include diffusers or other optical components configured to scatter light from the LEDs. Use of such components, however, typically reduces overall light output and increases manufacturing costs. Furthermore, in some cases, diffusers have limited effectiveness unless they are sufficiently spaced apart from corresponding light sources. This spacing can be a constraint on the sizing of light-emitting devices, e.g., preventing the thickness of light-emitting devices from being reduced.

FIG. 3 is a partially schematic cross-sectional view of a conventional light-emitting device 300 including a base 302, a plurality of LEDs 304 on the base 302, and a diffuser 306 above the LEDs 304, with a space 308 around the LEDs 304 between the base 302 and the diffuser 306. FIG. 4 is a plan view of the device 300 with the diffuser 306 removed for purposes of illustration. As shown in FIG. 4, the LEDs 304 (one labeled in FIG. 4) are distributed in an array having a regular distribution on the base 302. Wire bonds 310 extend between contacts (not shown) on the LEDs 304 and bond pads 312 on the base 302. The spacing (represented by dashed line 314 in FIG. 3) between the LEDs 304 and the diffuser 306 is approximately equal to the spacing (represented by dashed line 316 in FIG. 4) between neighboring LEDs 304 within the array. LEDs 304 typically behave as Lambertian emitters. With this in mind, the relative spacing between the LEDs 304 and the diffuser 306 shown in FIGS. 3-4 is often a minimum spacing necessary to cause the level of light incident on the diffuser 306 to be generally uniform across the area of the diffuser. Less spacing between the LEDs 304 and the diffuser 306 can prevent the diffuser 306 from adequately mitigating uneven light output. The relative spacing shown in FIGS. 3-4, however, can be impractical in some devices. For example, if the device 300 is a relatively large-area device, sufficient light output may be possible with widely spaced LEDs 304, but spacing the diffuser 306 a corresponding distance away from the LEDs 304 can cause the device 300 to be excessively thick.

For one or more of the reasons stated above and/or for other reasons not stated herein, there is a need for innovation in the field of SSRT devices. As one example, among others, there is a need for innovation directed to enhancing the uniformity of light output from light-emitting devices without unduly increasing manufacturing costs and/or constraining device sizing.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the principles of the present technology.

FIG. 1 is a partially schematic cross-sectional view illustrating an LED having a lateral configuration of electrical contacts in accordance with the prior art.

FIG. 2 is a partially schematic cross-sectional view illustrating an LED having a vertical configuration of electrical contacts in accordance with the prior art.

FIG. 3 is a partially schematic cross-sectional view illustrating a light-emitting device including multiple LEDs and a diffuser in accordance with the prior art.

FIG. 4 is a plan view of the device shown in FIG. 3 with the diffuser removed for purposes of illustration.

FIG. 5 is a partially schematic cross-sectional view illustrating a radiation-transducer device in accordance with an embodiment of the present technology.

FIG. 5-1 is an enlarged view of a portion of FIG. 5 illustrating details of a radiation transducer of the device shown in FIG. 5.

FIG. 6 is a plan view of the device shown in FIG. 5 with selected portions removed for purposes of illustration.

FIGS. 7-10 are partially schematic cross-sectional views illustrating radiation-transducer devices in accordance with additional embodiments of the present technology.

FIG. 10-1 is an enlarged view of a portion of FIG. 10 illustrating details of a radiation transducer of the device shown in FIG. 10.

FIG. 11 is a plan view of the device shown in FIG. 10 with selected portions removed for purposes of illustration.

FIG. 12 is a partially schematic cross-sectional view illustrating a radiation-transducer device in accordance with another embodiment of the present technology.

FIG. 12-1 is an enlarged view of a portion of FIG. 12 illustrating details of a radiation transducer of the device shown in FIG. 12.

FIG. 13 is a plan view of the device shown in FIG. 12 with selected portions removed for purposes of illustration.

FIGS. 14-17 are partially schematic cross-sectional views illustrating a semiconductor assembly after selected stages in a method for making radiation transducers of the radiation-transducer device shown in FIG. 5 or other suitable radiation transducers in accordance with an embodiment of the present technology.

FIGS. 18-21 are partially schematic cross-sectional views illustrating a radiation-transducer assembly after selected stages in a method for making the radiation-transducer device shown in FIG. 5 or other suitable radiation-transducer devices in accordance with an embodiment of the present technology.

FIG. 22 is a block diagram illustrating a system that incorporates a radiation-transducer device in accordance with an embodiment of the present technology.

### DETAILED DESCRIPTION

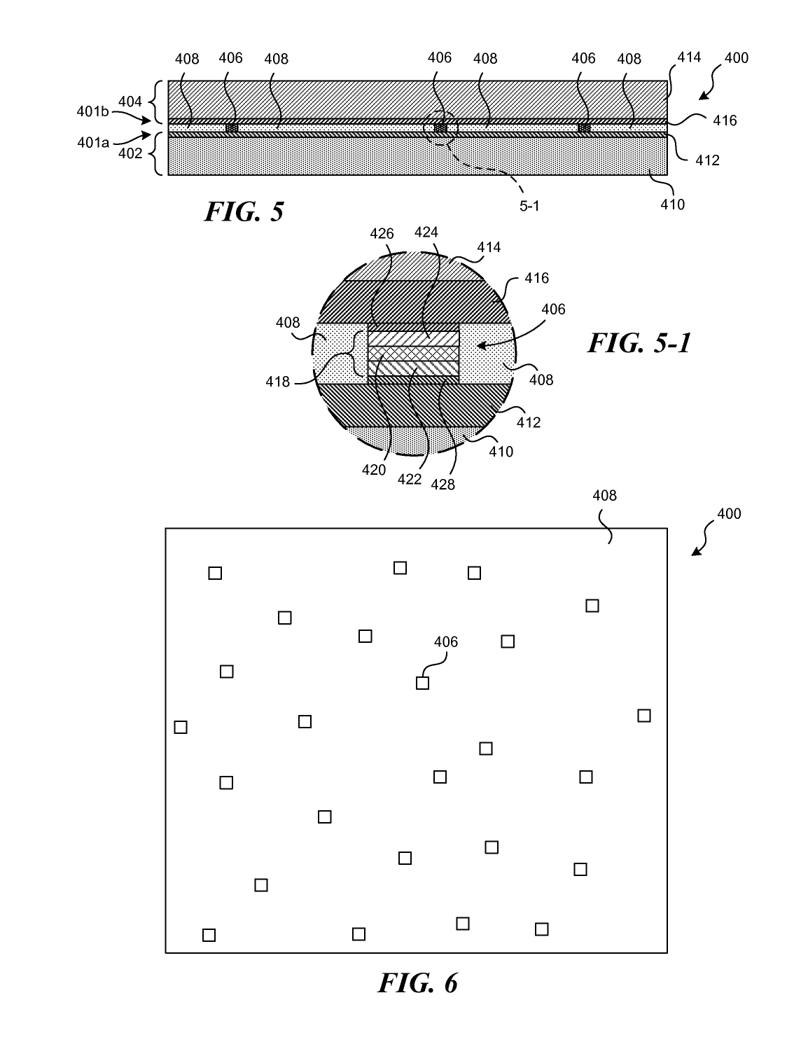

Specific details of several embodiments of radiation-transducer devices and associated systems and methods are described herein. The term “radiation transducer” generally refers to a solid-state component that includes semiconductor material as the active medium to convert electrical energy into electromagnetic radiation in the visible, ultraviolet, infrared, and/or other spectra. For example, radiation transducers can be solid-state light emitters (e.g., LEDs, laser diodes, etc.) and/or other sources of emission other than electrical filaments, plasmas, or gases. Radiation transducers can also be solid-state components that convert electromagnetic radiation into electricity. Furthermore, the term “device” can refer to a finished device or to an assembly or other structure at various stages of processing before becoming a finished device. Additionally, depending upon the context in which it is used, the term “substrate” can refer to a wafer-level substrate or to a singulated, die-level substrate. A person having ordinary skill in the relevant art will recognize that suitable stages of the processes described herein can be performed at the wafer level or at the die level. A person having ordinary skill in the relevant art will also understand that the present technology may have additional embodiments, and that the present technology may be practiced without several of the details of the embodiments described herein with reference to FIGS. 5-22.

For ease of reference, throughout this disclosure identical reference numbers are used to identify similar or analogous components or features, but the use of the same reference number does not imply that the parts should be construed to be identical. Indeed, in many examples described herein, the identically numbered parts are distinct in structure and/or function. Furthermore, the same shading is sometimes used to indicate materials in cross section that can be compositionally similar, but the use of the same shading does not imply that the materials should be construed to be identical.

FIG. 5 is a partially schematic cross-sectional view illustrating a radiation-transducer device 400 in accordance with an embodiment of the present technology. The device 400 can include a first conductive structure 401a, a second conductive structure 401b, and a plurality of radiation transducers 406, e.g., light-emitting diodes, electrically coupled to the conductive structures 401a-b. For example, the first conductive structure 401a can be a base structure 402, the second conductive structure 401b can be a cap structure 404, and the plurality of radiation transducers 406 can be between the base structure 402 and the cap structure 404. The device 400 can further include a fill material 408, e.g., a transparent underfill and/or adhesive, between the base structure 402 and the cap structure 404 around the transducers 406. In some embodiments, the device 400 does not include a diffuser and/or is not configured for use with a diffuser. In these and other embodiments, the sizes, spacing, and/or distribution of the transducers 406 can enhance the uniformity of the light output from the device 400 and reduce or eliminate the need for a diffuser. For example, the transducers 406 can be small enough to cause their individual light outputs to blend together and appear generally uniform. In some embodiments, the transducers 406 individually or on average have areas less than about 0.1 square millimeter, e.g., less than about 0.05 square millimeter or less than about 0.01 square millimeter. These areas, for example, can be the areas of optically active portions of the transducers 406, e.g., in a plane parallel to major surfaces of the base structure 402 and the cap structure 404. In other embodiments, the transducers 406 can have other suitable sizes.

As shown in FIG. 5, the base structure 402 can include a support 410 and a first lead 412 between the support 410 and the transducers 406. Similarly, the cap structure 404 can include a transparent support 414, e.g., a lens, and a second lead 416 between the transparent support 414 and the transducers 406. In some embodiments, the base structure 402, the cap structure 404, and the transducers 406 can be independently formed before being incorporated into the device 400. Suitable materials for the support 410 and the transparent support 414 include glass, silicone, and hard plastics (e.g., epoxy and acrylic), among others. The support 410 and the transparent support 414 can be configured to electrically insulate the first and second leads 412, 416, respectively. Suitable materials for the first and/or second leads 412, 416 include copper, aluminum, silver, and tungsten, among others. In some embodiments, the first and/or second leads 412, 416 can be at least partially transparent. Suitable transparent conductive materials include indium tin oxide, doped zinc oxide (e.g., aluminum-doped, gallium-doped, and indium-doped zinc oxide), and conductive polymers (e.g., polyaniline and poly(3,4-ethylenedioxythiophene)), among others. In some embodiments, for example, the first lead 412 includes a highly reflective conductive material, e.g., silver, and the second lead 416 includes a transparent conductive material. In other embodiments, both the first and second leads 412, 416 can be transparent. The first and/or second leads 412, 416 can be formed, for example, using electroplating, chemical vapor deposition, or other suitable techniques. In some embodiments, the first and/or second leads 412, 416 can include a pre-deposited solder (not shown), e.g., a thin-film solder, on a side facing the transducers 406.

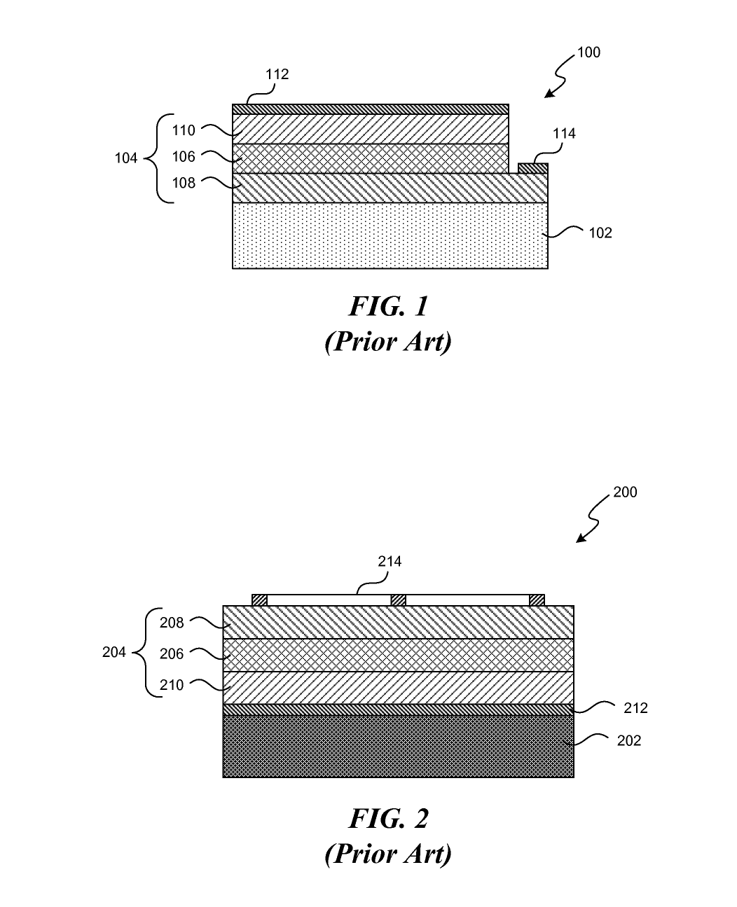

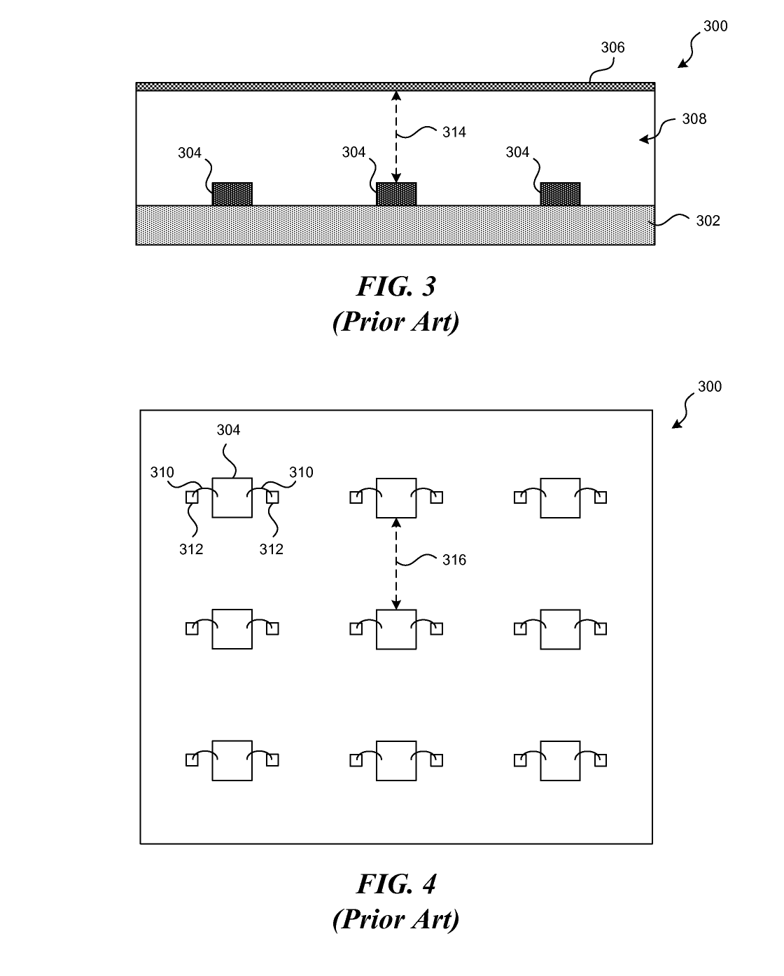

FIG. 5-1 is an enlarged view of a portion of FIG. 5 illustrating details of one of the transducers 406. As shown in FIG. 5-1, the transducer 406 can include a junction structure 418 having an active region 420 between an n-type material 422 and a p-type material 424. The transducer 406 can further include a first contact 426 electrically coupled to the p-type material 424 and a second contact 428 electrically coupled to the n-type material 422. The transducer 406 can have a vertical configuration with the first and second contacts 426, 428 on opposite sides of the transducer 406, but other configurations of the transducer 406 are also contemplated. As shown in FIGS. 5 and 5-1, the transducer 406 can be oriented between the first lead 412 and the second lead 416 such that the first contact 426 electrically couples the p-type material 424 to the second lead 416 and the second contact 428 electrically couples the n-type material 422 to the first lead 412. In other embodiments, the transducer 406 can have the opposite orientation or another suitable orientation with respect to the first and second leads 412, 416. The first and second contacts 426, 428 can be compositionally similar to the first and second leads 412, 416 and can be transparent or non-transparent. In some embodiments, reflowed solder (not shown) can be between the first contact 426 and the first lead 412 and/or between the second contact 428 and the second lead 416.

In contrast to the individual transducers 406, the device 400, the base structure 402, the cap structure 404, the first lead 412, the second lead 416, the support 410, and/or the transparent support 414 can have relatively large areas, e.g., greater than about 0.1 square meters, greater than about 0.2 square meters, greater than about 0.4 square meters, or other suitable sizes. Furthermore, the device 400 can be configured for independent use when connected to a power supply and can have a thickness perpendicular to the base structure 402 less than about 2 centimeters, e.g., less than about 1 centimeter or less than about 0.5 centimeters, or another suitable size. Accordingly, in some embodiments, the device 400 can serve as an ultra-thin, large-area emitter or receiver of optical energy. Ultra-thin, large-area emitters can be useful, for example, as backlights, displays, and panel-type light fixtures, among other applications. Furthermore, in some embodiments, the device 400 can be configured for use as a component of another device, e.g., as a lighting element of a larger backlight, display, light fixture, or other suitable assembly.

The device 400 can be configured to emit or receive light to or from the transducers 406 through the cap structure 404. Accordingly, the cap structure 404 can be at least partially transparent and the base structure 402 can be at least partially reflective to redirect light output from the transducers 406 toward the cap structure 404, as described above. This can be useful, for example, when the device 400 is configured for use with the base structure 402 facing a wall or ceiling. In other embodiments, the base structure 402 and the cap structure 404 can be at least partially transparent and the device 400 can be configured to emit light through both the base structure 402 and the cap structure 404. The base structure 402 and the cap structure 404 can define plates, which can be flexible or rigid. Furthermore, the device 400 can be flexible or rigid and can have a variety of suitable shapes, e.g., flat, curved, two-dimensional, three-dimensional, or other suitable shapes. In some embodiments, the device 400 can be initially manufactured in a first shape, e.g., a flat shape, and later modified into a different shape, e.g., a non-flat shape, during a later manufacturing stage or by an end user.

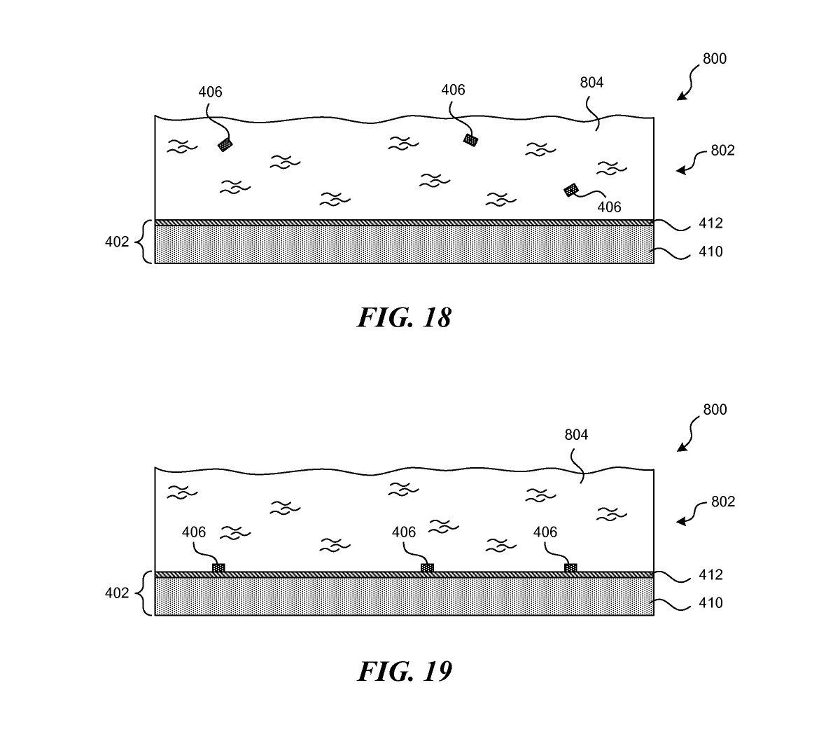

FIG. 6 is a plan view of the device 400 shown in FIG. 5 with the cap structure 404 removed for purposes of illustration. With reference to FIGS. 5-6, the transducers 406 (one labeled in FIG. 6) can have an irregular distribution between the base structure 402 and the cap structure 404. For example, the transducers 406 can be randomly positioned or otherwise positioned in an irregular pattern, e.g., non-uniformly, randomly, and/or unequally spaced apart in a plane parallel to the base structure 402 and/or the cap structure 404. In other embodiments, the distribution of the transducers 406 can be regular, e.g., with uniform, repeating, and/or equal spacing. In some cases, collective light output from irregularly, e.g., randomly, distributed light sources can have a more uniform actual or perceived appearance than collective light output from regularly distributed light sources. In other cases, regularly distributed light sources can be advantageous. The transducers 406 can be distributed, for example, without individual handling, which can allow large numbers of the transducers 406 to be operably positioned at relatively low cost. Suitable techniques for distributing the transducers 406 are described below with reference to FIGS. 18-21. The density of the transducers 406, e.g., the average spacing between the transducers 406, can be controlled to change the level of light output from the device 400. In some embodiments, the combined area of the active regions 420 parallel to the base structure 402 is less than about 2%, e.g., less than about 1% or less than about 0.5%, of an area of the device 400, the base structure 402, the cap structure 404, the first lead 412, the second lead 416, the support 410, or the transparent support 414. Furthermore, the fill material 408 can extend over greater than about 98%, e.g., greater than about 99% or greater than about 99.5%, of a plane extending through the transducers 406.

With reference to FIGS. 5-6, in some embodiments, the first lead 412 defines a first conductive field and/or the second lead 416 defines a second conductive field. The conductive fields can be continuous or patterned and can be single fields or collections of sub fields. When the conductive fields are patterned, the patterns can be generally without gaps larger than the areas of the first or second contacts 426, 428 of the transducers 406. The conductive fields can extend over relatively large areas, e.g., greater than about 0.1 square meters, greater than about 0.2 square meters, or greater than about 0.4 square meters, and can extend between multiple transducers 406, e.g., between generally all of the transducers 406 of the device 400. This can facilitate distributing the transducers 406 into operable positions without individual handling and/or placement of the transducers 406. For example, in some cases, when the conductive fields have relatively large areas and the transducers 406 have relatively small areas, the transducers 406 can be relatively indiscriminately positioned with respect to the conductive fields and still be operable. The conductive fields can be connected to electrical terminals (not shown) of the device 400. In some embodiments, the first and/or second lead 412, 416 can include traces (not shown) between the terminals and different portions of the conductive fields to enhance current spreading. These traces, for example, can be distributed to different portions of the conductive fields along sides of the conductive fields opposite sides facing the transducers 406.

The first and second contacts 426 and 428 of the transducers 406 can be generally uniformly or non-uniformly oriented with respect to the first and second leads 412, 416. A first plurality of the transducers 406 can have a first orientation with the first contact 426 toward the base structure 402 and the second contact 428 toward the cap structure 404, and a second plurality of the transducers 406 can have a second orientation with the first contact 426 toward the cap structure 404 and the second contact 428 toward the base structure 402. For example, the first and second contacts 426 and 428 of the transducers 406 can be non-uniformly and randomly oriented with respect to the first and second leads 412, 416, e.g., in a generally Gaussian distribution. In some embodiments, greater than about 10%, e.g., greater than about 20% or greater than about 30%, of the transducers 406 have the first orientation and greater than about 10%, e.g., greater than about 20% or greater than about 30%, of the transducers 406 have the second orientation. In some cases, when the transducers 406 are diodes and the first and second contacts 426 and 428 of the transducers 406 are non-uniformly oriented with respect to the first and second leads 412, 416, current can flow through the transducers 406 having one of the first and second orientations but not through the transducers 406 having the other of the first and second orientations. For example, in some cases, when the device 400 is configured to convey a direct current between the first and second leads 412, 416, the transducers 406 having the first orientation are operational, but the transducers 406 having the second orientation are non-operational. In these embodiments, a cost savings associated with eliminating or reducing individual handling and/or placement of the transducers 406 can be greater than the cost of the non-operational transducers 406.

In other embodiments, the device 400 can be configured to convey an alternating current such that the transducers 406 having the first orientation and the transducers 406 having the second orientation are operational at opposing phases of the alternating current. For example, the transducers 406 having the first orientation can be activated when current passes between the first and second leads 412, 416 in a positive phase, e.g., first direction, while the transducers 406 having the second orientation can be activated when current passes between the first and second leads 412, 416 in a negative phase, e.g., a second direction opposite the first direction. Each portion of the transducers 406 can be activated intermittently, but at a sufficiently high frequency that the light emission from the device 400 appears continuous. In these and other embodiments, the number of the transducers 406 having the first orientation and the number of the transducers 406 having the second orientation can be approximately equal to reduce reverse breakdown of the transducers 406. In some embodiments, the transducers 406 can have reverse breakdown voltages generally sufficient to prevent reverse breakdown during operation of the device 400 when the transducers 406 are randomly oriented within about two standard deviations of a Gaussian distribution.

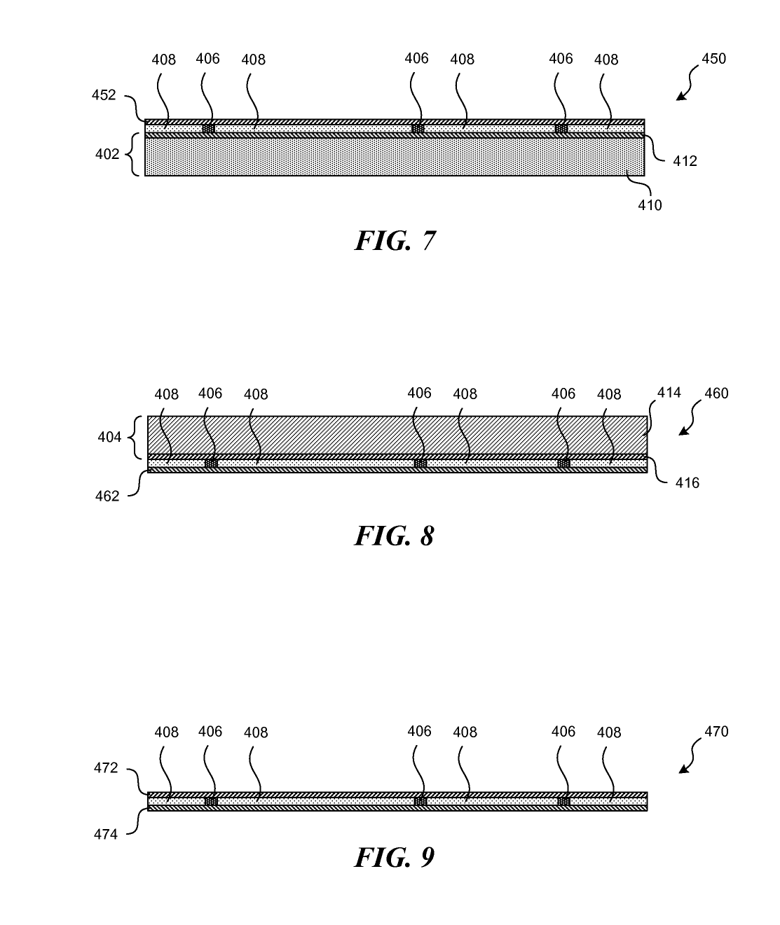

FIGS. 7-9 are partially schematic cross-sectional views illustrating radiation-transducer devices 450, 460, 470 in accordance with additional embodiments of the present technology. As shown in FIGS. 7-9, in some embodiments, the support 410 and/or the transparent support 414 shown in FIG. 5 can be eliminated. The radiation-transducer device 450 shown in FIG. 7 can include a cap structure 452 similar to the cap structure 404 shown in FIG. 5 without the transparent support 414. The radiation-transducer device 460 shown in FIG. 8 can include a base structure 462 similar to the base structure 402 shown in FIG. 5 without the support 410. The radiation-transducer device 470 shown in FIG. 9 can include a cap structure 472 similar to the cap structure 404 shown in FIG. 5 without the transparent support 414 and a base structure 474 similar to the base structure 402 shown in FIG. 5 without the support 410. The radiation-transducer devices 450, 460, 470 can be configured to be embedded in an encapsulant and/or used with one or more separate electrically insulating components, e.g., shell components. Other suitable configurations are also possible. For example, in some embodiments, some or all of the fill material 408 shown in FIGS. 5 and 7-9 can be eliminated.

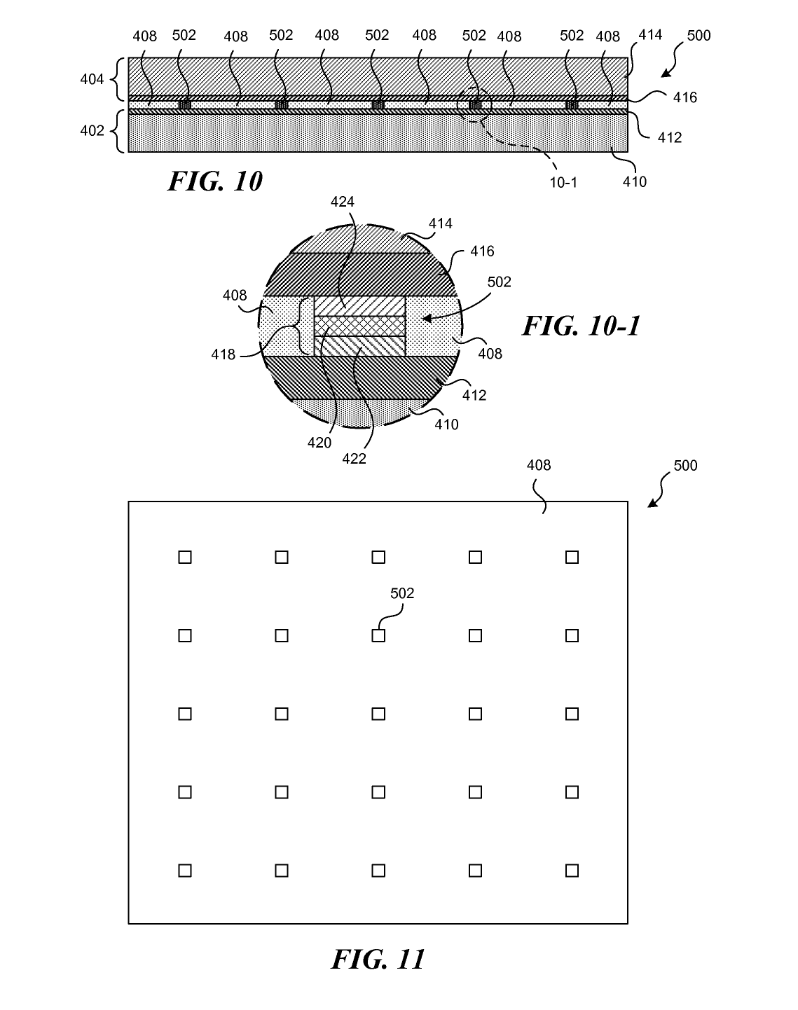

FIG. 10 is a partially schematic cross-sectional view illustrating a radiation-transducer device 500 in accordance with another embodiment of the present technology. The device 500 can include a plurality of radiation transducers 502, e.g., light-emitting diodes, having different configurations than the transducers 406 show in FIGS. 5-6. FIG. 10-1 is an enlarged view of a portion of FIG. 10 illustrating details of one of the transducers 502. As shown in FIG. 10-1, the transducer 502 can include the junction structure 418 without the first and second contacts 426, 428 described above with reference to FIG. 5-1. Instead, the n-type material 422 can be directly coupled to the first lead 412 and the p-type material 424 can be directly coupled to the second lead 416 without intervening contacts. In some embodiments, reflowed solder (not shown) can be between n-type material 422 and the fist lead 412 and/or between the p-type material 424 and the second lead 416. Eliminating contacts on the transducers 502 can be useful, for example, to reduce manufacturing costs, to improve light transmission, and/or to reduce sizing constraints. FIG. 11 is a plan view of the device 500 shown in FIG. 10 with the cap structure 404 removed for purposes of illustration. As shown in FIG. 11, the transducers 502 (one labeled in FIG. 11) can have a regular distribution, e.g., the transducers 502 can be distributed in an array having uniform, repeating, or equal spacing. In some embodiments, the transducers 502 can be individually handled, e.g., robotically positioned, to achieve the regular distribution.

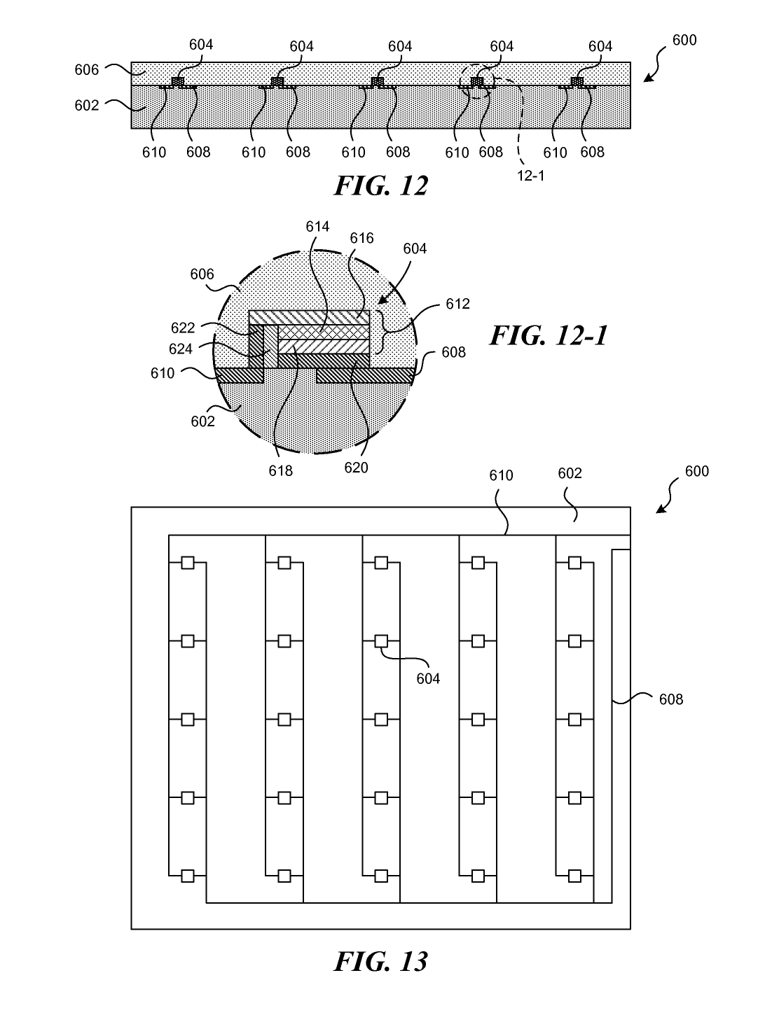

FIG. 12 is a partially schematic cross-sectional view illustrating a radiation-transducer device 600 in accordance with another embodiment of the present technology. The device 600 can include a base structure 602, and a plurality of radiation transducers 604, e.g., light-emitting diodes, on the base structure 602. The device 600 can further include a fill material 606, e.g., a transparent fill material, on the base structure 602 and the transducers 604. As shown in FIG. 12, the base structure 602 can include a first lead 608 and a second lead 610. FIG. 13 is a plan view of the device 600 shown in FIG. 12 with the fill material 606 removed for purposes of illustration. As shown in FIG. 13, the transducers 604 (one labeled in FIG. 13) can have a regular distribution, e.g., the transducers 604 can be distributed in an array having uniform, repeating, or equal spacing. In some embodiments, the transducers 604 can be individually handled, e.g., robotically positioned, to achieve the regular distribution. Furthermore, the first and second leads 608, 610 can define patterned traces. Including both the first and second leads 608, 610 in the base structure 602 can be useful, for example, to reduce the need for transparent conductive materials and/or to further reduce sizing constraints.

The transducers 604 shown in FIGS. 12-13 can have different configurations than the transducers 406 show in FIGS. 5-6 and the transducers 502 shown in FIGS. 10-11. FIG. 12-1 is an enlarged view of a portion of FIG. 12 illustrating details of one of the transducers 604. As shown in FIG. 12-1, the transducer 604 can include a junction structure 612 having an active region 614 between an n-type material 616 and a p-type material 618. The transducer 604 can further include a first contact 620 electrically coupled to the p-type material 618, a second contact 622 electrically coupled to the n-type material 616, and a dielectric barrier 624 between the first and second contacts 620, 622. The transducer 604 can have a lateral configuration with the first and second contacts 620, 622 on the same side of the transducer 604. As shown in FIGS. 12 and 12-1, the transducer 604 can be positioned such that the first contact 620 electrically couples the p-type material 618 to the first lead 608 and the second contact 622 electrically couples the n-type material 616 to the second lead 610. In some embodiments, reflowed solder (not shown) can be between the first contact 620 and the first lead 608 and/or between the second contact 622 and the second lead 610. In other embodiments, wire bonds (not shown) or other suitable electrical connectors can extend between the first contact 620 and the first lead 608 and/or between the second contact 622 and the second lead 610.

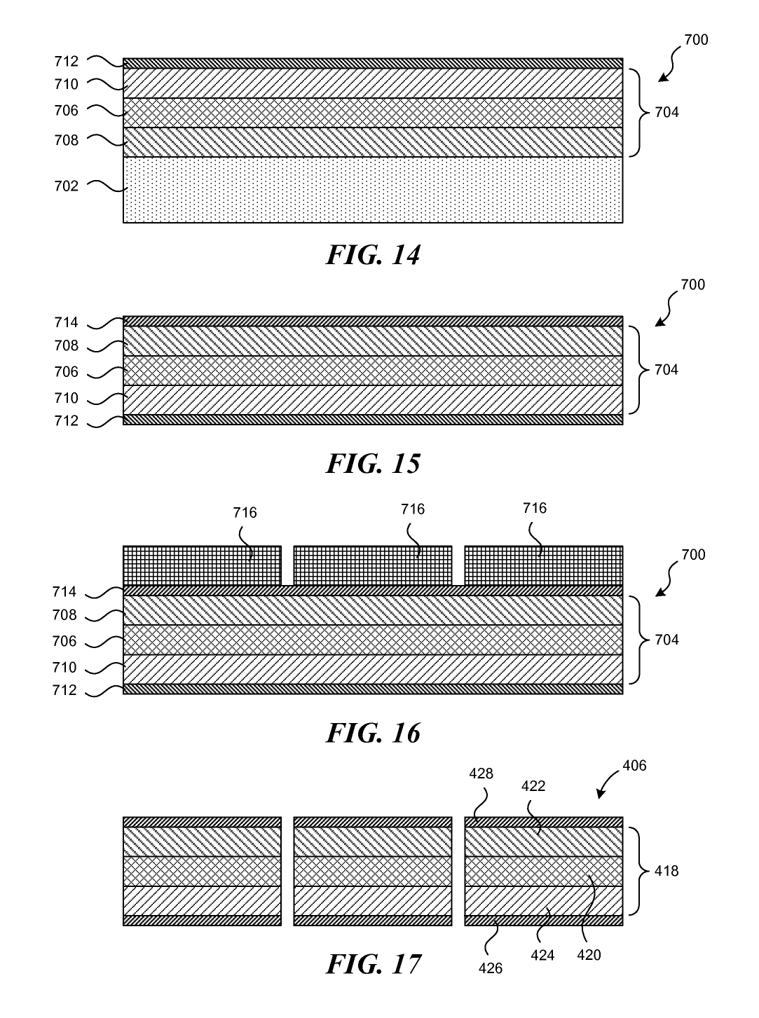

FIGS. 14-17 are partially schematic cross-sectional views illustrating a portion of a semiconductor assembly 700 after selected stages in a method for making the transducers 406 shown in FIGS. 5-6 or other transducers in accordance with an embodiment of the present technology. Only selected stages are shown to illustrate certain aspects of the present technology. The semiconductor assembly 700 can include a growth substrate 702 under a junction structure 704 having an active region 706 between an n-type material 708 and a p-type material 710. As shown in FIG. 14, a first conductive material 712 can be formed on the p-type material 710 using electroplating, chemical vapor deposition, or other suitable techniques. In some embodiments, the first conductive material 712 can include a highly reflective conductive material, e.g., silver. Other suitable materials include, for example, copper, aluminum, and tungsten. As shown in FIG. 15, the growth substrate 702 can be removed by backgrinding, and the semiconductor assembly 700 can be inverted. A second conductive material 714 can then be formed on the n-type material 708 using electroplating, chemical vapor deposition, or other suitable techniques. In some embodiments, the second conductive material 714 can include a transparent conductive material, e.g., indium tin oxide or doped zinc oxide. As shown in FIG. 16, a photoresist 716 can be formed on the second conductive material 714 and patterned using suitable photolithography techniques. As shown in FIG. 17, the semiconductor assembly 700 can then be etched to singulate the transducers 406 (one labeled in FIG. 17) using plasma etching or other suitable techniques. After etching, the remaining photoresist 716 can be removed, e.g., using plasma ashing, wet cleans, or other suitable techniques. In some embodiments, solder (not shown), e.g., a suitable thin-film solder, can be pre-deposited on the first conducive material 712, the second conductive material 714, the first contact 426, and/or the second contact 428.

A variety of suitable variations of the method shown in FIGS. 14-17 can be used to form the transducers 406 shown in FIGS. 5-6. For example, the semiconductor assembly 700 can be releasably attached to a temporary substrate (not shown) before or after removing the growth substrate 702. Furthermore, although the method shown in FIGS. 14-17 is described primarily with respect to forming the transducers 406 shown in FIGS. 5-6, the method can be adapted to form other suitable transducers. For example, forming the first and second conductive materials 712, 714 can be eliminated and the method can be used to form the transducers 502 shown in FIGS. 10-11. In these embodiments, for example, solder (not shown), e.g., a suitable thin-film solder, can be pre-deposited on the n-type material 708, 422 and/or the p-type material 710, 424.

FIGS. 18-21 are partially schematic cross-sectional views illustrating a radiation-transducer assembly 800 after selected stages in a method for making the device 400 shown in FIG. 5 or other suitable radiation-transducer devices in accordance with an embodiment of the present technology. Only selected stages are shown to illustrate certain aspects of the present technology. In some embodiments, the method includes distributing the transducers 406 without individually handling the transducers 406. Although FIGS. 18-21 are described primarily with respect to distributing the transducers 406 initially onto the base structure 402, the same or similar techniques can also be used with respect to distributing the transducers 406 initially onto the cap structure 404. As shown in FIG. 18, a mixture 802 including the transducers 406 and a non-solid carrier medium 804 can be introduced, e.g., dispensed or otherwise deposited, onto the base structure 402. Suitable techniques for depositing the mixture 802 include ink jet dispensing, spin coating, and submersing or dipping the base structure 402 in the mixture 802, among others. When the mixture 802 is dispensed using an ink-jet, the mixture 802 can be selectively deposited onto the base structure 402 in a pre-determined pattern. In other embodiments, the mixture 802 can coat the base structure 402 using spin-coating, submersion, or dipping processes.

As shown in FIG. 19, after introducing the mixture 802, the transducers 406 can settle onto the base structure 402. This can include, for example, allowing the transducers 406 to settle by gravity alone or in combination with lifting the base structure 402 through the mixture 802, electrophoresis, agitating the mixture 802, agitating the base structure 402, applying a magnetic field to the mixture 802, and/or other suitable techniques. Other techniques for distributing the transducers 406, e.g., without individually handling the transducers 406, are also possible. For example, the transducers 406 can be scattered, e.g., dropped though a gaseous medium, onto the base structure 402. The transducers 406 can settle, for example, into an irregular, e.g., random, distribution on the base structure 402.

The transducers 406 can be distributed onto the base structure 402 such that they become uniformly or non-uniformly oriented with respect to the first and second leads 412, 416 when the device 400 is assembled. In some embodiments, the transducers 406 have two major sides and generally settle with one of the two sides facing the base structure 402. For example, the transducers 406 can be shaped such the surfaces between the two major sides are edges upon which the transducers 406 generally do not come to rest. The distribution of orientations of the transducers 406, e.g., according to the side facing the base structure 402, can be random, e.g., Gaussian. In other embodiments, the transducers 406 and/or the settling process can be controlled to cause the transducers to predominantly or entirely have the same orientation. For example, the transducers 406 can be configured to self orient as they settle within the carrier medium 804. In some embodiments, the transducers 406 can be asymmetrically shaped and/or weighted about a plane parallel to their active regions 420 and/or major surfaces such that they preferentially orient in free fall through a Newtonian fluid. Furthermore, magnets or other features can be incorporated into the transducers 406 to facilitate preferential orientation of the transducers 406 under a field, e.g., a magnetic field, applied during settling.

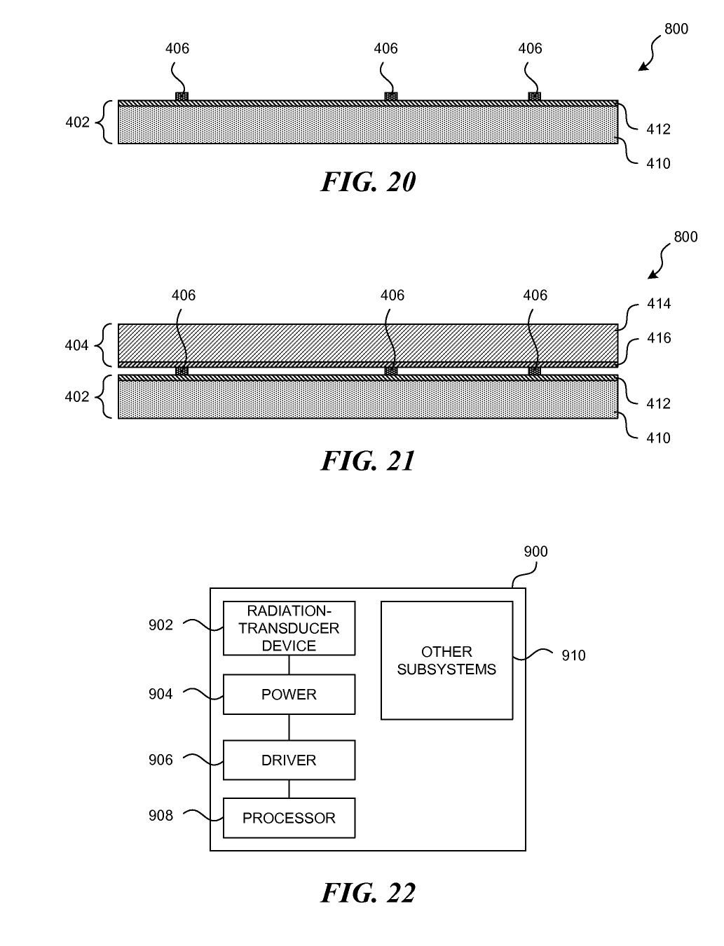

As shown in FIG. 20, after the transducers 406 settle onto the base structure 402, the carrier medium 804 can be removed, e.g., by evaporation. The carrier medium 804 can be selected such that it generally does not leave a residue or any undesirable contamination after removal. Suitable carrier media 804 include, for example, ultrapure water, among others. As shown in FIG. 21, the cap structure 404 can be placed onto the transducers 406 after the carrier medium 804 has been removed. When the transducers 406, the base structure 402, and/or the cap structure 404 include pre-deposited solder, the solder can be reflowed to mechanically and/or electrically couple the transducers 406 to the first and/or second leads 416. With reference to FIG. 5, a precursor of the fill material 408, e.g., uncured silicone or epoxy, can be injected or otherwise introduced, e.g., underfilled, between the base structure 402 and the cap structure 404. The solidity of precursor can then be increased, e.g., the precursor can be cured by applying microwave energy, to form the fill material 408. The fill material 408 can mechanically bond the base structure 402 to the cap structure 404. In some embodiments, the carrier medium 804 is a precursor of the fill material 408. For example, after the transducers 406 settle onto the base structure 402, the solidity of the carrier medium 804 can be increased to form the fill material 408. In some embodiments, excess carrier medium 804 and/or fill material 408 can be removed, e.g., using a suitable mechanical or chemical-mechanical removal technique, before or after increasing the solidity of the carrier medium 804.

Any of the radiation-transducer devices described herein with reference to FIGS. 5-21 can be incorporated into any of a myriad of larger and/or more complex systems, a representative example of which is the system 900 shown schematically in FIG. 22. The system 900 can include a radiation-transducer device 902, a power source 904, a driver 906, a processor 908, and/or other suitable subsystems or components 910. The system 900 can be configured to perform any of a wide variety of suitable functions, such as backlighting, general illumination, power generation, sensing, and/or other functions. Furthermore, the system 900 can include, without limitation, hand-held devices (e.g., cellular or mobile phones, tablets, digital readers, and digital audio players), lasers, photovoltaic cells, remote controls, computers, and appliances (e.g., refrigerators). Components of the system 900 can be housed in a single unit or distributed over multiple, interconnected units, e.g., through a communications network. The components of the system 900 can also include local and/or remote memory storage devices, and any of a wide variety of suitable computer-readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein.

Throughout this disclosure, the singular terms “a,” “an,” and “the” include plural referents unless the context clearly indicates otherwise. Similarly, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same feature and/or additional types of other features are not precluded. Directional terms, such as “upper,” “lower,” “front,” “back,” “vertical,” and “horizontal,” may be used herein to express and clarify the relationship between various elements. It should be understood that such terms do not denote absolute orientation. Reference herein to “one embodiment,” “an embodiment,” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

I/We claim:

1. A radiation-transducer device, comprising:
a base structure including a first lead;
a cap structure including a second lead; and
a plurality of radiation transducers distributed in an irregular pattern between the base structure and the cap structure.

2. The radiation-transducer device of claim 1, wherein the radiation transducers are generally randomly spaced apart in a plane parallel to the base structure.

3. The radiation-transducer device of claim 1, wherein the radiation transducers are generally non-uniformly spaced apart in a plane parallel to the base structure.

4. The radiation-transducer device of claim 1, wherein the radiation transducers are generally unequally spaced apart in a plane parallel to the base structure.

5. The radiation-transducer device of claim 1, wherein the cap structure further includes a lens extending over an area greater than about 0.1 square meters.

6. The radiation-transducer device of claim 1, further comprising a fill material between the base structure and the cap structure, wherein the fill material extends over greater than about 98% of a plane extending through the radiation transducers.

7. The radiation-transducer device of claim 1, further comprising solder connections between the radiation transducers and the first lead, between the radiation transducers and the second lead, or both.

8. The radiation-transducer device of claim 1, wherein the radiation transducers individually include:
a p-type material electrically coupled to one of the first lead and the second lead,
an n-type material electrically coupled to other of the first lead and the second lead, and
an active region between the p-type material and the n-type material.

9. The radiation-transducer device of claim 8, wherein:
a first plurality of the radiation transducers are oriented such that the p-type material faces toward the cap structure and the n-type material faces toward the base structure; and
a second plurality of the radiation transducers are oriented such that the p-type material faces toward the base structure and the n-type material faces toward the cap structure.

10. The radiation-transducer device of claim 8, wherein the radiation transducers individually further include:
a first contact on a first side of the radiation transducer between the p-type material and the one of the first lead and the second lead; and
a second contact on a second side of the radiation transducer between the n-type material and the other of the first lead and the second lead.

11. The radiation-transducer device of claim 8, wherein:
the cap structure further includes a transparent material;
the base structure is at least partially reflective;
the second lead is at least partially transparent;
a first plurality of the radiation transducers are oriented such that the p-type material faces toward the cap structure and the n-type material faces toward the base structure; and
a second plurality of the radiation transducers are oriented such that the p-type material faces toward the base structure and the n-type material faces toward the cap structure.

12. The radiation-transducer device of claim 8, wherein:
the first lead includes a first conductive field;
the second lead includes a second conductive field; and
the p-type material and the n-type material individually are electrically coupled to the first conductive field or the second conductive field.

13. The radiation-transducer device of claim 12, wherein the first conductive field has an area greater than about 0.1 square meters.

14. The radiation-transducer device of claim 1, wherein the radiation transducers are non-uniformly oriented with respect to the first lead and the second lead.

15. The radiation-transducer device of claim 14, wherein the radiation transducers are generally randomly oriented with respect to the first lead and the second lead.

16. The radiation-transducer device of claim 14, wherein the radiation-transducer device is configured to convey an alternating current between the first lead and the second lead.

17. The radiation-transducer device of claim 1, wherein the radiation transducers are generally uniformly oriented with respect to the first lead and the second lead.

18. The radiation-transducer device of claim 17, wherein the radiation transducers are at least partially self orienting.

19. The radiation-transducer device of claim 18, wherein the radiation transducers are asymmetrically shaped about a plane parallel to the active region such that the radiation transducers preferentially orient in free fall through a Newtonian fluid.

20. The radiation-transducer device of claim 18, wherein the radiation transducers are asymmetrically weighted about a plane parallel to the active region such that the radiation transducers preferentially orient in free fall through a Newtonian fluid.

21. A radiation-transducer device, comprising:
a base structure including a first lead with a first conductive field;
a cap structure including a second lead with a second conductive field; and
a plurality of radiation transducers distributed between the base structure and the cap structure, wherein the radiation transducers individually include
a p-type material electrically coupled to one of the first conductive field and the second conductive field,
an n-type material electrically coupled to other of the first conductive field and the second conductive field, and
an active region between the p-type material and the n-type material.

22. The radiation-transducer device of claim 21, wherein the plurality of radiation transducers is distributed in a regular pattern between the first conductive field and the second conductive field.

23. A lighting-emitting device, comprising:
a first lead structure including a base and a first lead having a first conductive field;
a second lead structure including a second lead having a second conductive field; and
a plurality of light-emitting diodes distributed between the first lead and the second lead, the light-emitting diodes individually including
a p-type material electrically coupled to one of the first lead and the second lead,
an n-type material electrically coupled to other of the first lead and the second lead, and
an active region between the p-type material and the n-type material,
wherein the light-emitting diodes are irregularly oriented with respect to the first lead and the second lead with a first plurality of the light-emitting diodes having a first orientation with the p-type material electrically coupled to the first lead, and a second plurality of the light-emitting diodes having a second orientation with the n-type material electrically coupled to the first lead.

24. The lighting-emitting device of claim 23, wherein the first lead structure and the second lead structure are flexible.

25. The lighting-emitting device of claim 23, wherein the light-emitting diodes are generally randomly oriented with respect to the first lead and the second lead.

26. The lighting-emitting device of claim 23, wherein the second lead structure further includes a lens extending over an area greater than about 0.1 square meters.

27. The lighting-emitting device of claim 23, further comprising a fill material between the first lead structure and the second lead structure, wherein the fill material extends over greater than about 98% of a plane extending through the light-emitting diodes.

28. The lighting-emitting device of claim 23, wherein greater than about 10% of the light-emitting diodes have the first orientation, and greater than about 10% of the light-emitting diodes have the second orientation.

29. The lighting-emitting device of claim 28, wherein the lighting-emitting device is configured to convey a direct current between the first lead and the second lead such that the light-emitting diodes having the first orientation are operational and the light-emitting diodes having the second orientation are non-operational or the light-emitting diodes having the first orientation are non-operational and the light-emitting diodes having the second orientation are operational.

30. The lighting-emitting device of claim 28, wherein the lighting-emitting device is configured to convey an alternating current between the first lead and the second lead such that the light-emitting diodes having the first orientation are activated when current passes between the first lead and the second lead in a first direction and the light-emitting diodes having the second orientation are activated when current passes between the first lead and the second lead in a second direction opposite the first direction.

31. A lighting-emitting device, comprising:
a base structure including a first lead and a second lead; and
an array of light-emitting diodes over the base structure, wherein the light-emitting diodes individually include
a p-type material electrically coupled to the first lead,
an n-type material electrically coupled to the second lead,
an active region between the p-type material and the n-type material,
a first contact on a first side of the light-emitting diode between the p-type material and the first lead, and
a second contact on the first side of the light-emitting diode between the n-type material and the second lead,
wherein a combined area of the active regions parallel to the base structure is less than about 2% of an area of the base structure, and the area of the base structure is greater than about 0.1 square meters.

32. The lighting-emitting device of claim 31, wherein the lighting-emitting device is configured for use without a diffuser.

33. The lighting-emitting device of claim 31, wherein:
the lighting-emitting device is configured for independent use when connected to a power supply; and
the lighting-emitting device has a thickness perpendicular to the base structure less than about 2 centimeters.

34. A radiation-transducer device, comprising:
a first conductive structure;
a second conductive structure; and
radiation transducers individually including
a p-type material,
an n-type material, and
an active region between the p-type material and the n-type material,
wherein the p-type material of a first plurality of the radiation transducers is electrically coupled to the first conductive structure, and the n-type material of a second plurality of the radiation transducers is electrically coupled to the first conductive structure.

35. The radiation-transducer device of claim 34, wherein the n-type material of the first plurality of the radiation transducers is electrically coupled to the second conductive structure, and the p-type material of the second plurality of the radiation transducers is electrically coupled to the second conductive structure.

36. The radiation-transducer device of claim 34, wherein the first and second conductive structures are conductive fields.

37. A method for manufacturing a radiation-transducer device, comprising:
distributing a plurality of radiation transducers in an irregular pattern onto one of a base structure including a first lead and a cap structure including a second lead such that the radiation transducers have first sides proximate the one of the base structure and the cap structure;
positioning the other of the base structure and the cap structure at second sides of the radiation transducers opposite the first sides; and
electrically connecting the radiation transducers between the first lead and the second lead.

38. The method of claim 37, further comprising singulating the radiation transducers by selectively etching a wafer including the radiation transducers before distributing the radiation transducers.

39. The method of claim 37, further comprising underfilling a space around the radiation transducers between the first lead and the second lead after positioning the other of the base structure and the cap structure.

40. The method of claim 37, wherein distributing the radiation transducers does not include individually handling the radiation transducers.

41. The method of claim 37, wherein distributing the radiation transducers does not include uniformly orienting the radiation transducers with respect to the first lead and the second lead.

42. The method of claim 37, wherein distributing the radiation transducers includes scattering the radiation transducers onto the one of the base structure and the cap structure.

43. The method of claim 37, further comprising:
pre-depositing solder onto the radiation transducers, the first lead, the second lead, or a combination thereof; and
reflowing the solder after distributing the radiation transducers.

44. The method of claim 37, wherein distributing the radiation transducers includes introducing a mixture including the radiation transducers and a non-solid carrier medium onto the one of the base structure and the cap structure.

45. The method of claim 44, wherein introducing the mixture includes inkjet dispensing.

46. The method of claim 44, wherein distributing the radiation transducers further includes settling the radiation transducers onto the one of the base structure and the cap structure, and removing the non-solid carrier medium after settling the radiation transducers.

47. The method of claim 44, wherein distributing the radiation transducers further includes settling the radiation transducers onto the one of the base structure and the cap structure, and increasing the solidity of the non-solid carrier medium after settling the radiation transducers.

48. The method of claim 44, wherein distributing the radiation transducers further includes settling the radiation transducers onto the one of the base structure and the cap structure such that the radiation transducers self-orient within the non-solid carrier medium.
